(19) United States
(12) Patent Application Publication
(10) Pub. No.: US 2023/0235219 A1
(43) Pub. Date: Jul. 27, 2023

(54) LOW-DIMENSIONAL PEROVSKITE-STRUCTURED METAL HALIDE AND PREPARATION METHOD AND APPLICATION THEREOF

(71) Applicant: SHANGHAI INSTITUTE OF CERAMICS, CHINESE ACADEMY OF SCIENCES, Shanghai (CN)

(72) Inventors: Yuntao WU, Shanghai (CN); Shuangliang CHENG, Shanghai (CN); Qian WANG, Shanghai (CN); Jian SHI, Shanghai (CN); Huanying LI, Shanghai (CN); Guohao REN, Shanghai (CN)

(21) Appl. No.: 18/001,748

(22) PCT Filed: Jun. 10, 2021
(86) PCT No.: PCT/CN2021/099440

§ 371 Date: Dec. 14, 2022

(30) Foreign Application Priority Data
Jun. 22, 2020 (CN) 202010573954.7
Apr. 25, 2021 (CN) 202110446361.9

(51) Int. Cl. C09K 11/61; C30B 11/02; C30B 28/12; C30B 29/12; G01T 1/202; G01T 1/20

(52) U.S. Cl. CPC C09K 11/616; C30B 11/02; C30B 28/12; C30B 29/12; G01T 1/202; G01T 1/2018

(57) ABSTRACT

The present invention provides a low-dimensional perovskite-structured metal halide and a preparation method and application thereof. The general formulas of the compositions of the low-dimensional perovskite-structured metal halide are AB₂X₃, A₂BX₃, and A₃B₂X₅; wherein, A is at least one of Li, Na, K, Rb, Cs, In, and Tl; B is at least one of Cu, Ag, and Au; and X is at least one of F, Cl, Br, and I.

### TECHNICAL FIELD

The present invention relates to a low-dimensional perovskite-structured metal halide and a preparation method and application thereof, and specifically relates to an intrinsically luminescent halide scintillation crystal or a thallium-doped low-dimensional perovskite-structured microcrystalline scintillation film and a preparation method and application thereof, which belong to the technical field of scintillation materials or lead-free perovskite films.

### BACKGROUND

A scintillator is a material that can convert high-energy rays or particles into visible light or ultraviolet light, and has been widely used in the field of radiation detection. With the continuous improvement of the performance requirements of radiation detection materials in application fields such as homeland security, nuclear medical imaging, and high-energy physics, it is urgent to develop a novel high-performance scintillator.

At present, thallium-doped sodium iodide (NaI:Tl⁺) is a main scintillator used in the field of security inspection internationally. As a widely used commercial scintillation material, such a material has the advantages of high light output (about 40,000 photons/MeV) and low cost, but it has poor energy resolution (about 7% at 662 keV), which limits its application in high-resolution nuclide detection and is prone to deliquesce in air, requiring encapsulation before use.

In order to overcome these disadvantages, many novel scintillators have been developed internationally in recent years, and among them, the main scintillators with outstanding properties are cerium-doped lanthanum bromide (LaBr₃:Ce³⁺) and europium-doped strontium iodide (SrI₂:Eu²⁺). Both materials can achieve a high energy resolution of 2.6% at 662 keV, while both have higher light output than NaI:Tl. However, the LaBr3:Ce material has a radioactive background of ¹³⁸La, which affects its performance in identifying weak radiation sources; while the SrI₂:Eu material has a strong self-absorption effect, the scintillation property thereof will be significantly decreased when the crystal size is larger. In addition, similar to NaI:Tl, both materials have strong deliquescence and are extremely unstable in the atmospheric environment, greatly increasing the preparation cost and application difficulty.

The aforementioned scintillation materials all have the disadvantage of deliquescence in the air, which is common in halide scintillators. Due to this disadvantage, halide scintillation crystals usually need to be tightly encapsulated before use, which has a great impact on the cost of material storage and use. At present, the non- (or weakly) deliquescent halide scintillator with relatively wide application is mainly thallium-doped cesium iodide (CsI:Tl⁺). This material has a high light output, equivalent to that of NaI:Tl, and is inexpensive, but its long afterglow limits its use in high-resolution imaging. The CsI:Tl crystal also has the problem of non-uniformity of luminescence. This is because Tl⁺ ions are non-uniformly distributed throughout the crystal due to the segregation of components, resulting in a non-uniform scintillation property of the crystal. This disadvantage is common to all doped luminescent scintillation crystals, and will inevitably decrease the final energy resolution of materials.

Moreover, in recent years, perovskite-structured materials have become a subject of research interest in the field of scintillation materials because of their excellent optical and electrical properties. They usually have unique characteristics in light absorption and photoluminescence, such as suitable and adjustable direct bandgap, low-temperature processability, high absorption coefficient, long carrier diffusion distance, high carrier mobility and low defect density, and have shown tremendous application potential in photoelectric detectors and other fields, as well as a certain application prospect in the field of radiation detection, such as security inspection and medical imaging. Low-dimensional perovskite-structured halide materials with the characteristic of confined exciton luminescence have the advantages of large Stokes shift and high fluorescence quantum efficiency. Some of them have shown certain X-ray detection performance, but still cannot completely surpass the existing X-ray detection materials. Therefore, it is urgent to develop a novel low-dimensional perovskite-structured scintillation thin film material with high light yield, high quantum efficiency and low afterglow, which is of great significance for the leap-forward improvement of the performance of X-ray imaging detectors.

### SUMMARY

In view of the aforementioned problems and demands in the prior art, the present invention is intended to provide a low-dimensional perovskite-structured metal halide (AB₂X₃, A₂BX₃, and A₃B₂X₅ scintillation crystals with intrinsic luminescence or thallium-doped low-dimensional perovskite-structured microcrystalline scintillation thin film) and a preparation method and application thereof. The low-dimensional perovskite-structured metal halide has the advantages of high energy resolution, high light output, non-deliquescence, high uniformity, and low afterglow, etc., and can be widely used in the field of radiation detection.

In a first aspect, the present invention provides a low-dimensional perovskite-structured metal halide, and the general formulas of the compositions of the low-dimensional perovskite-structured metal halide are AB₂X₃, A₂BX₃, and A₃B₂X₅, wherein A is at least one of Li, Na, K, Rb, Cs, In, and Tl; B is at least one of Cu, Ag, and Au; and X is at least one of F, Cl, Br, and I.

Preferably, the general formulas of the compositions of the low-dimensional perovskite-structured metal halide are (A₁₋ₓA′ₓ)(B_{1-y}B′_{y}) ₂(X_{1-z}X′_{z})₃, (A₁₋ₓA′ₓ)₂(B_{1-y}B′_{y})(X_{1-z}X′_{z})₃, and (A₁₋ₓA′ₓ)₃(B_{1-y}B′_{y})₂(X_{1-z}X′_{z})₅, wherein A and A′ are at least two of Li, Na, K, Rb, Cs, In, and Tl; B and B′ are at least two of Cu, Ag, and Au; X and X′ are at least two of F, Cl, Br, and I; and x is greater than 0 and less than 1, y is greater than 0 and less than 1, and z is greater than 0 and less than 1.

Preferably, the general formulas of the compositions of the low-dimensional perovskite-structured metal halide are (A_{1-a-b}A′ₐTl_{b})(B_{1-c}B′_{c})₂(X_{1-d}X’_{d})₃, (A_{1-a-b}A′ₐTl_{b})₂(B_{1-c}B′_{c})(X₁₋_{d}X’_{d})₃, and (A_{1-a-b}A′ₐTl_{b})₃(B_{1-c}B′_{c})₂(X_{1-d}X’_{d})₅, wherein A and A′ are at least one of Li, Na, K, Rb, Cs, and In; B and B′ are at least one of Cu, Ag, and Au; X and X′ are F, Cl, Br, and I; a is greater than or equal to 0 and less than 1, b is greater than 0 and less than or equal to 1, c is greater than or equal to 0 and less than or equal to 1, and d is greater than or equal to 0 and less than or equal to 1; preferably, the general formula of the composition of the low-dimensional perovskite-structured metal halide is (A_{1-a-b}A′ₐTl_{b})₃(B_{1-c}B′_{c})₂(X_{1-d}X’_{d})₅, wherein A is Cs, B is Cu, X is I, a, c, and d are equal to 0, and b is greater than 0 and less than or equal to 0.1.

Preferably, when the general formulas of the compositions of the low-dimensional perovskite-structured metal halide are AB₂X₃, A₂BX₃, and A₃B₂X₅, wherein A is at least one of Li, Na, K, Rb, Cs, In, and Tl; B is at least one of Cu, Ag, and Au; and X is at least one of F, Cl, Br, and I; and the form of the low-dimensional perovskite-structured metal halide may be a low-dimensional perovskite-structured metal halide scintillation crystal (i.e., an intrinsically luminescent halide scintillation crystal). The luminescent mechanism of all the aforementioned three scintillation crystals is self-trapped exciton recombination luminescence. Self-trapped exciton (STE) recombination luminescence is an excited-state transient defect. When the material is excited by light, a strong coupling effect occurs between electrons and phonons, which induces transient distortion of the excited-state lattice and further captures photogenerated electrons, that is, self-trapped lattice. The captured photogenerated electrons then release energy in the form of recombination luminescence, thus exhibiting a broad-spectrum emission behavior.

Preferably, when the general formulas of the compositions of the low-dimensional perovskite-structured metal halide are (A_{1-a-b}A′ₐTl_{b})(B_{1-c}B′_{c})₂(X_{1-d}X’_{d})₃, (A_{1-a-b}A′ₐTl_{b})₂(B₁₋_{c}B′_{c})(X_{1-d}X’_{d})₃, and (A_{1-a-b}A′ₐTl_{b})₃(B_{1-c}B′_{c})₂(X_{1-d}X’_{d})₅, wherein A and A′ are at least one of Li, Na, K, Rb, Cs, and In; B and B′ are at least one of Cu, Ag, and Au; X and X′ are F, Cl, Br, and I; a is greater than or equal to 0 and less than 1, b is greater than 0 and less than or equal to 1, c is greater than or equal to 0 and less than or equal to 1, and d is greater than or equal to 0 and less than or equal to 1 (preferably, the general formula of the composition of the low-dimensional perovskite-structured metal halide is (A_{1-a-b}A′ₐTl_{b}) ₃(B_{1-c}B′_{c})₂(X_{1-d}X’_{d})₅, wherein A is Cs, B is Cu, X is I, a, c, and d are equal to 0, and b is greater than 0 and less than or equal to 0.1), and the form of the low-dimensional perovskite-structured metal halide may also be a thallium-doped low-dimensional perovskite-structured metal halide microcrystalline scintillation thin film.

The low-dimensionality of the present invention is different from the low-dimensionality at the structural level (i.e., two-dimensional thin film, one-dimensional nanowire, zero-dimensional quantum dot, etc.), but is expressed at the molecular level. In a bulk perovskite crystal, if a network structure cannot be formed between central polyhedrons in three directions, it is considered to be a low-dimensional perovskite at the molecular level. A polyhedron is divided by large atoms or groups of atoms in one or more directions, forming polyhedral planes, polyhedral lines, or independent polyhedrons at the molecular level.

In the present invention of the thallium-doped low-dimensional perovskite-structured metal halide microcrystalline scintillation thin film, (B_{1-c}B′_{c})₂(X_{1-d}X’_{d})⁻₃, (B_{1-c}B′_{c})(X_{1-d}X’_{d})²⁻₃, and (B_{1-c}B′_{c})₂(X_{1-d}X’_{d})³⁻₅ atomic groups are separated by (AA′)⁺ atoms to form the aforementioned low-dimensional structure. This structure enables excitons to be strongly confined in a single polyhedron, polyhedron chain, or polyhedral plane, reducing non-radiative coupling and increasing luminescent efficiency. In addition, thallium doping is beneficial to the generation of more excitons in the lattice, and increases the utilization rate of excitons and light output.

Preferably, among the three general formulas of the compositions of the thallium-doped low-dimensional perovskite-structured microcrystalline thin film, (A_{1-a-b}A′ₐTl_{b})₃(B₁₋_{c}B′_{c})₂(X_{1-d}X’_{d})₅ microcrystalline thin film has a relatively good effect. Elements at the three positions are selected as follows: A and A′ are preferably atoms with large ionic radius (such as Cs); B and B′ are preferably atoms which are likely to form a compound (such as Cu); and X and X′ are preferably atoms with large ionic radius (such as I). The luminescent characteristics of microcrystalline thin films composed of different elements are different. More preferably, the thallium-doped low-dimensional perovskite-structured microcrystalline thin film has the following general formula: (A_{1-a-b}A′ₐTl_{b})₃(B_{1-c}B′_{c})₂(X_{1-d}X’_{d})₅, wherein A is Cs, B is Cu, X is I, a, c, and d are equal to 0, and b is greater than 0 and less than or equal to 0.1.

Preferably, the X-ray excited luminescence of the thallium-doped low-dimensional perovskite-structured microcrystalline scintillation thin film is 350 nm to 1200 nm.

Preferably, the coating material of the thallium-doped low-dimensional perovskite-structured microcrystalline scintillation thin film is a single-source coating material or a dual-source coating material; the single-source coating material is a thallium-doped low-dimensional perovskite-structured compound synthesized according to (A_{1-a-b}A′ₐTl_{b})(B_{1-c}B′_{c})₂(X_{1-d}X’_{d})₃, (A₁₋ₐ₋_{b}A′ₐTl_{b})₂(B_{1-c}B′_{c})(X_{1-d}X’_{d})₃, or (A_{1-a-b}A′ₐTl_{b})₃(B_{1-c}B′_{c})₂(X_{1-d}X’_{d})₅; and the dual-source coating material is a thallium-free low-dimensional perovskite-structured compound and thallium halide, or a synthesized thallium-doped low-dimensional perovskite-structured compound and thallium halide.

In a second aspect, the present invention also provides a preparation method for the aforementioned intrinsically luminescent halide scintillation crystal, which adopts the Bridgman method to prepare the halide scintillation crystal.

Preferably, the preparation method includes:
(1) weighing AX and BX as raw materials respectively according to the general formula of the composition of the halide scintillation crystal, mixing the materials, placing the mixture into a crucible under inert gas, nitrogen, or anhydrous environment, vacuumizing, and sealing the crucible by welding;
(2) placing the sealed crucible into a Bridgman furnace, then heating up to a temperature exceeding the melting points of the raw materials by 50° C. to 100° C. so that the materials are completely melted, subsequently adjusting the temperature of the bottom of the crucible to decrease to the melting point of the halide scintillation crystal, and starting crystal growth at a descending rate of 0.1 mm/h to 10.0 mm/h; and
(3) after the crystal growth is completed, cooling to room temperature to give a halide scintillation crystal.

Preferably, the crucible is a quartz crucible with a conical bottom or a capillary bottom.

Preferably, the purity of the raw materials is greater than or equal to 99.9%.

Preferably, the inert gas is argon.

In a third aspect, the present invention further provides an application of the aforementioned intrinsically luminescent halide scintillation crystal in the fields of neutron detection imaging, X-ray detection imaging, and γ-ray detection imaging, such as medical imaging, security inspection, petroleum exploration wells, and industrial testing.

In a fourth aspect, the present invention further provides a radiation detector containing the aforementioned intrinsically luminescent halide scintillation crystal.

In a fifth aspect, the thallium-doped low-dimensional perovskite-structured microcrystalline scintillation thin film may be prepared by thermal evaporation, sputtering, or other coating methods.

In a sixth aspect, the present invention provides a method for preparing the aforementioned thallium-doped low-dimensional perovskite-structured microcrystalline scintillation thin film by a thermal evaporation method based on the principle of physical vapor deposition, comprising: placing a substrate into a vacuum coating device, loading coating material into an evaporation boat with a corresponding volume, controlling the vacuum degree and temperature of the vacuum coating device, and starting coating.

Preferably, the purity of the high-purity halide raw materials is 99.99%.

Preferably, when the coating material is loaded into the evaporation boat with the corresponding volume, an evaporation boat containing thallium halide is added to evaporate synchronously with the existing thallium-doped low-dimensional perovskite-structured compound (the preparation method includes: weighing halides of B, B′, X, X′, A, and A′ and thallium halide as high-purity materials with a purity of 99.99% according to the molar ratio of the chemical formula of the composition of the thin film; and, under an inert gas environment, loading all the materials into a quartz tube, heating the crucible above the melting points of the materials so that the materials are completely melted, mixing uniformly, and cooling to synthesize the existing thallium-doped low-dimensional perovskite-structured compound); and the mass ratio of the thallium-doped low-dimensional perovskite-structured compound to thallium halide is a molar ratio of 99.99:0.01 to 90:10. This setting is intended to avoid asynchronous evaporation caused by a large difference in melting points between the halide raw materials and TlX.

Preferably, the vacuum coating device is vacuumized until the vacuum degree is lower than 10⁻² Pa, and the substrate is heated to 20° C. to 300° C.; after the vacuum degree and the temperature of the substrate are stable, the coating procedure is started, and the coating raw material is heated to a molten state until the evaporation is completed.

Preferably, for the dual-source coating process, the thallium-doped low-dimensional perovskite-structured compound is heated to a molten state, and thallium halide is heated to a nearly sublimated state.

In a seventh aspect, the present invention provides a method for preparing the aforementioned thallium-doped low-dimensional perovskite-structured microcrystalline scintillation thin film by a sputtering method based on the principle of physical vapor deposition, comprising: placing a substrate on a tray in a vacuum chamber of a sputtering system, loading the coating material on a cathode target position, installing a baffle between a target and the tray; controlling the vacuum degree and temperature of the sputtering system, and starting coating.

Preferably, the sputtering system is controlled, so that the vacuum degree is lower than 10⁻² Pa, the substrate is heated to 20° C. to 300° C., and an inert gas is introduced as a sputtering working gas; when the vacuum degree and the temperature of substrate are stable, the switch of a radio-frequency power supply is turned on to perform pre-sputtering; after the pre-sputtering, sputtering is started while maintaining the sputtering conditions until sputtering is completed.

In an eighth aspect, the present invention provides an application of the aforementioned thallium-doped low-dimensional perovskite-structured microcrystalline scintillation thin film in X-ray medical imaging and neutron detection imaging. When X-rays are used to irradiate the human body, the intensities of the X-rays passing through the bones or tissues with different densities and thicknesses in the human body are different. The thallium-doped low-dimensional perovskite-structured microcrystalline thin film provided by the present invention is utilized to convert the intensity distribution of X-rays into the intensity distribution of visible light and collects visible light information, so that an X-ray image visible to the human eyes can be obtained. The principle of neutron imaging is the same as that of X-ray imaging.

### Beneficial Effects

In the present invention, the intrinsically luminescent halide scintillation crystal (or referred to as intrinsic halide scintillation crystal) has the advantages of intrinsic luminescence, high energy resolution, high light output, low afterglow, non-deliquescence, etc., and the crystal is easy to prepare in a large size. Compared with polycrystalline thin film scintillators, monocrystalline scintillators have higher lattice integrity and crystal quality, so the monocrystalline scintillators with the same composition have higher scintillation efficiency. In addition, the polycrystalline thin film scintillators can only be used for X-ray detection because they cannot deposit the energy of high-energy rays and particles due to the limitation of thin film thickness. In contrast, the monocrystalline scintillators as bulk materials not only can detect X-rays, but also can realize the detection of high-energy rays and particles.

In the present invention, compared with conventional CsI:Tl, the thallium-doped low-dimensional perovskite has a completely different structure. Polyhedron centers composed of Cu and Ag halides are independent of each other to a certain extent, which makes excitons have strong confinement effect and avoids non-radiative coupling, thus having an extremely high luminescent efficiency. However, the CsI:Tl crystal does not have a similar structure for confinement of excitons, so there is a strong non-radiative coupling.

Compared with CsI:Tl, the thallium-doped low-dimensional perovskite-structured microcrystalline thin film provided by the present invention has the advantages of high scintillation detection efficiency, high light output, adjustable luminescent wavelength, non-deliquescence, low afterglow, no self-absorption, etc., is expected to obtain higher radiation detection imaging quality, can be used for detecting X-rays and neutrons, and has important application prospects in the fields of medical imaging, security inspection, industrial testing, etc.

### BRIEF DESCRIPTION OF DRAWINGS

FIG. 1 shows photos of ingots and samples of intrinsically luminescent halide scintillation crystals with different compositions;

FIG. 2 shows X-ray excited emission spectrums of the intrinsically luminescent halide scintillation crystals with different compositions;

FIG. 3 shows pulse height spectrums excited by ¹³⁷Cs radioactive source of the intrinsically luminescent halide scintillation crystals with different compositions;

FIG. 4 shows scintillation decay times of the intrinsically luminescent halide scintillation crystals with different compositions;

FIG. 5 shows a schematic structural diagram of a radiation detector;

a of FIG. 6 shows a photo of a sample of a microcrystalline thin film obtained in Example 6 under the irradiation of natural light, and b of FIG. 6 shows a photo of the sample of the microcrystalline thin film obtained in Example 6 under ultraviolet light irradiation;

FIG. 7 shows an absorption spectrum of the microcrystalline thin film obtained in Example 6;

a of FIG. 8 shows a fluorescence spectrum of the microcrystalline thin film obtained in Example 6 under excitation at 300 nm, and b of FIG. 8 shows a fluorescence spectrum of the microcrystalline thin film obtained in Example 6 under excitation at 335 nm;

FIG. 9 shows fluorescence decay times of the two emission peaks (shown in FIG. 8) of the microcrystalline thin film obtained in Example 6;

FIG. 10 shows an X-ray excited emission spectrum of the microcrystalline thin film obtained in Example 6;

FIG. 11 shows an X-ray excited emission spectrum of the microcrystalline thin film obtained in Example 8;

FIG. 12 shows the scintillation decay time of the microcrystalline thin film obtained in Example 6;

FIG. 13 shows an afterglow curve of the microcrystalline thin film obtained in Example 6; and

FIG. 14 shows a schematic diagram of a detector composed of the microcrystalline thin film obtained in Example 6 and a photodetector.

### DETAILED DESCRIPTION OF PREFERRED EMBODIMENTS

The present invention will be further illustrated by the following embodiments below, and it should be understood that the following embodiments are only used to illustrate the present invention rather than to limit it.

In the present disclosure, a novel intrinsically luminescent halide scintillator with the advantages of non-deliquescence, high energy resolution, high light output and short decay time is provided, which has great value in the field of radiation detection.

The novel intrinsically luminescent halide scintillation crystal has a polycrystalline or monocrystalline structure, and has the following general formulas of compositions: (A₁₋ₓA′ₓ)(B₁₋_{y}B′_{y})₂(X_{1-z}X′_{z})₃, (A₁₋ₓA′ₓ)₂(B_{1-y}B′_{y})(X_{1-z}X′_{z})₃, and (A₁₋ₓA′ₓ)₃(B_{1-y}B′_{y}) ₂(X_{1-z}X′_{z})₅, wherein A and A′ are Li, Na, K, Rb, Cs, In, and Tl; B and B′ are Cu, Ag, and Au; X and X′ are F, Cl, Br, and I; and x is greater than 0 and less than or equal to 1, y is greater than 0 and less than or equal to 1, and z is greater than 0 and less than or equal to 1.

In an embodiment of the present invention, the halide scintillation crystal is prepared by the Bridgman method. An exemplary illustration of the growth process of the halide scintillation crystal is described below.

Selection of Bridgman Furnace. The Bridgman furnace (used) consists of three sections: high-temperature zone, low-temperature zone, and crystallization zone.

Mixture. Raw materials are weighed respectively according to the general formula of composition ((A₁₋ₓA′ₓ)(B_{1-y}B′_{y})₂(X_{1-z}X′_{z})₃, (A₁₋ₓA′ₓ)₂(B_{1-y}B′_{y})(X_{1-z}X′_{z})₃, or (A₁₋ₓA′ₓ)₃(B_{1-y}B′_{y})₂(X₁₋_{z}X′_{z})₅) and mixed to obtain a mixture. The selected materials may be one or more of AX and BX, wherein A is Li, Na, K, Rb, Cs, In, and Tl; B is Cu, Ag, and Au; and X is F, Cl, Br, and I. The purity of all the materials is above 99.9%. As a further preferred solution, the materials need to be dried under vacuum before being weighed and proportioned, and the drying temperature is less than or equal to 180° C.

Loading. The mixture is loaded into a quartz crucible with a V-shaped bottom (conical bottom) or capillary bottom under inert gas, nitrogen, or anhydrous environment. The crucible is then vacuumized and sealed by welding. The inert gas environment is a glove box filled with argon. The nitrogen environment is a glove box filled with nitrogen. The vacuum degree of vacuumization is better than (<) 10⁻² Pa.

Melting. The sealed quartz crucible is vertically placed in the high-temperature zone of the crystal growing furnace, and the crystal growing furnace is heated to a temperature exceeding the melting points of the materials by 50° C. to 100° C. until the materials are completely melted and uniformly mixed.

Bridgman growth. The position of crucible and the temperature of furnace are then adjusted so that the temperature of the bottom of the crucible is decreased to the melting point of the halide scintillation crystal, the quartz crucible is then descended in the furnace body at a descending rate of 0.1 mm/h to 10.0 mm/h, and crystals start to nucleate and grow from the capillary bottom of the crucible until the melt is completely solidified. The temperature is then decreased at a rate of 5° C. /h to 50° C. /h to room temperature. Finally, the prepared halide scintillation crystal is taken out of the quartz crucible.

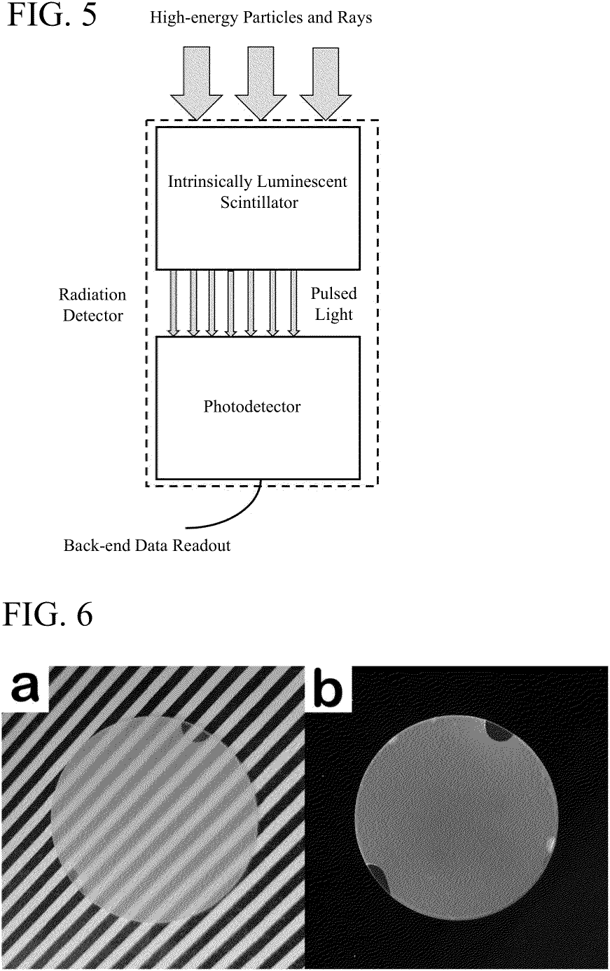

In the present invention, the obtained intrinsically luminescent halide scintillation crystal has the advantages of non-deliquescence, high energy resolution, high light output and short decay time, and has a good application prospect in the field of neutron detection, X-ray detection, or γ-ray detection. For example, the structure of a radiation detector composed of the intrinsically luminescent halide scintillation crystal provided by the present invention and a photodetector is shown in FIG. 5. When high-energy particles and rays irradiate the intrinsically luminescent halide scintillation crystal, pulsed light signals are formed based on its intrinsic luminescence characteristic and transmitted to the photodetector, and data of the high-energy particles and rays can be directly read at a back end.

In the present disclosure, the thallium-doped low-dimensional perovskite-structured microcrystalline thin film has the following general formulas: (A_{1-a-b}A′ₐTl_{b})(B_{1-c}B′_{c})₂(X_{1-d}X’_{d})₃, (A_{1-a-b}A′ₐTl_{b})₂(B_{1-c}B′_{c})(X_{1-d}X’_{d})₃, and (A_{1-a-b}A′ₐTl_{b})₃(B_{1-c}B′_{c})₂(X_{1-d}X’_{d})₅, wherein A and A′ are at least one of Li, Na, K, Rb, Cs, and In; B and B′ are at least one of Cu, Ag, and Au; X and X′ are F, Cl, Br, and I; and a is greater than or equal to 0 and less than 1, b is greater than 0 and less than or equal to 1, c is greater than or equal to 0 and less than or equal to 1, and d is greater than or equal to 0 and less than or equal to 1.

An exemplary illustration of an operation process of preparing the thallium-doped low-dimensional perovskite-structured microcrystalline thin film by a vacuum coating method is described below.

Weighing of high-purity halide materials. High-purity halide materials are weighed according to the general formulas of the compositions ((A_{1-a-b}A′ₐTl_{b})(B_{1-c}B′_{c})₂(X_{1-d}X’_{d})₃, (A₁₋ₐ₋_{b}A′ₐTl_{b})₂(B_{1-c}B′_{c})(X_{1-d}X’_{d})₃, or (A_{1-a-b}A′ₐTl_{b})₃(B₁-_{c}B′_{c})₂(X_{1-d}X’_{d})₅).

Synthesis of Coating Material. In an inert gas environment, all the materials are loaded into a quartz tube, the crucible temperature is increased above the melting points of the materials, so that the materials are completely melted and uniformly mixed, and after cooling, a coating material (thallium-doped low-dimensional perovskite-structured compound, thallium-free low-dimensional perovskite-structured compound and thallium halide TlX (X is F, Cl, Br, or I), or thallium-doped low-dimensional perovskite-structured compound and thallium halide TlX (X is F, Cl, Br, or I)) is synthesized. The inert gas environment may be a glove box filled with argon or nitrogen.

Cleaning and drying. A substrate made of TFT glass or other materials as a coating substrate is ultrasonically cleaned by deionized water, absolute ethanol, or acetone and dried.

Coating by thermal evaporation. According to different initial coating materials, a single-source, dual-source, or triple-source evaporation method may be used. Since thallium halide usually has a low melting point or sublimation point, in the coating process, the coating may fail to exhibit thallium doping or the concentration of thallium doping may be too low due to the great difference in vaporization temperature between thallium halide and other materials. The single-source method of the present invention refers to the direct use of a thallium-doped compound as an evaporation source, while the dual-source method uses excessive TlX as another evaporation source to supplement Tl loss in the process of evaporation. As an example, a clean and dry substrate is placed in a vacuum coating device, and the obtained coating material is loaded into an evaporation boat with a corresponding volume. In order to avoid asynchronous evaporation caused by great difference between the melting points of the halide material and that of TlX, an evaporation boat loaded with bead-like thallium halide may be additionally added for synchronous evaporation with the existing thallium-doped low-dimensional perovskite-structured compound. The aforementioned vacuum coating device may be vacuumized below 10⁻³ Pa, and the substrate is heated to 20° C. to 300° C. When the vacuum degree and the temperature of the substrate become stable, current heating is started, input power is gradually adjusted until the vacuum degree decreases, the coating procedure is started, the thallium-doped low-dimensional perovskite-structured compound is heated into a molten state, and TlX is heated into a molten or nearly sublimed state. After evaporation is completed, a heating unit is turned off, and the temperature is naturally decreased to room temperature. The obtained thallium-doped low-dimensional perovskite-structured microcrystalline thin film is stored in a dry environment.

An exemplary illustration of an operation process of preparing the thallium-doped low-dimensional perovskite-structured microcrystalline thin film by a sputtering method is described below.

Weighing of high-purity halide materials. Halide materials with high-purity are weighed according to the general formulas of the compositions ((A_{1-a-b}A′ₐTl_{b})(B_{1-c}B′_{c})₂(X_{1-d}X’_{d})₃, (A_{1-a-b}A′ₐTl_{b})₂(B_{1-c}B′_{c})(X_{1-d}X’_{d})₃, or (A_{1-a-b}A′ₐTl_{b})₃(B_{1-c}B′_{c})₂(X_{1-d}X’_{d})₅).

Synthesis of coating material. In inert gas or anhydrous environment, the materials are loaded into a quartz tube, and a quartz crucible is then vacuumized and sealed by welding. The temperature of crucible is increased above the melting points of the materials, so that the materials are completely melted and uniformly mixed, and after cooling, a coating material (thallium-doped low-dimensional perovskite-structured compound, thallium-free low-dimensional perovskite-structured compound and thallium halide TlX (X is F, Cl, Br, or I), or thallium-doped low-dimensional perovskite-structured compound and thallium halide TlX (X is F, Cl, Br, or I)) is synthesized.

Cleaning and drying. A substrate made of TFT glass or other materials as a coating substrate is ultrasonically cleaned by deionized water, absolute ethanol, or acetone, and dried.

Coating by sputtering. The clean and dry substrate is placed on a tray in a vacuum chamber of a sputtering system, a target made of the coating material is placed on a cathode target position, and a baffle is installed between the target and the tray. The vacuum coating device is vacuumized until the vacuum degree is lower than 10⁻³ Pa. The substrate is heated to 20° C. to 300° C., and high-purity argon is injected as a sputtering working gas. When the vacuum degree and the temperature of substrate reach destinate values, a radio-frequency power supply is switched on, input power is increased to a sputtering power, and pre-sputtering is carried out while maintaining working gas pressure. After pre-sputtering, sputtering is started while maintaining sputtering conditions. After sputtering is completed, the injection of the working gas is stopped, and the system returns to normal pressure. Sputtering and heating units are turned off, and the temperature is decreased to room temperature. The obtained low-dimensional perovskite-structured microcrystalline thin film is stored in a dry environment.

Examples will be taken to further illustrate the present invention in detail below. It should also be understood that the following examples are only used to further illustrate the present invention rather than to limit the protection scope of the present invention. All non-essential improvements and adjustments which are made by those skilled in the art according to the above contents of the present invention shall fall within the protection scope of the present invention. The specific technological parameters of the following examples are merely one example in an appropriate range, that is, those skilled in the art can make choices within the appropriate range through the description herein, but the choices are not limited to the specific values of the following examples.

### Example 1:

The chemical formula of the composition of the intrinsically luminescent halide scintillation crystal proposed in Example 1 is CsCu₂I₃, i.e., (A₁₋ₓA′ₓ)(B_{1-y}B′_{y})₂(X_{1-z}X′_{z})₃ as the general formula, with A being Cs, B being Cu, X being I, and x, y, and z being equal to 0.

The aforementioned intrinsically luminescent halide scintillation crystal was prepared by the Bridgman method, comprising the following steps:

(a) Raw materials were weighed according to the chemical formula (CsCu₂I₃) of the composition of the intrinsically luminescent halide scintillation crystal to be prepared. During specific operation, high-purity materials CsI and CuI with a purity of 99.99% were weighed according to the molar ratio of CsCu₂I₃.

(b) In an inert gas environment, the raw materials were loaded into a quartz crucible with a capillary bottom; and the crucible was then vacuumized and sealed by welding. In this example, the inert gas environment was a glove box filled with argon or nitrogen.

(c) The sealed quartz crucible was vertically placed at the middle position in a crystal growing furnace, the crystal growing furnace was heated to about 650° C. (±30° C.) until the materials were completely melted and uniformly mixed, the crucible position and the furnace temperature were adjusted so that the temperature of the bottom of the crucible was decreased to about 380° C. (±30° C.), then the quartz crucible was descended at a descending rate of 0.4 mm/h in the furnace body, and crystals started to nucleate and grow from the capillary bottom of the crucible until the melt was completely solidified. Subsequently the temperature was lowered at a rate of 10° C./h to room temperature, and finally, a prepared halide scintillation crystal was taken out of the quartz crucible in a dry temperature and processed.

The aforementioned intrinsically luminescent halide scintillation crystal is used in the field of neutron detection, X-ray detection, or γ-ray detection.

The result of an X-ray excited emission spectrum test shows that the CsCu₂I₃ scintillation crystal has strong X-ray excited luminescence. The result of γ-ray pulse height spectrum test shows that the CsCu₂I₃ scintillation crystal has a good γ-ray response, and there is a full-energy peak at 662 keV under the excitation of ¹³⁷Cs radioactive source.

### Example 2:

The chemical formula of the composition of the intrinsically luminescent halide scintillation crystal proposed in Example 2 is Cs₃Cu₂I₅, i.e., (A₁₋ₓA′ₓ)₃(B_{1-y}B′_{y})₂(X_{1-z}X′_{z})₅ as the general formula, with A being Cs, B being Cu, X being I, and x, y, and z being equal to 0.

The aforementioned intrinsically luminescent halide scintillation crystal was prepared by the Bridgman method, comprising the following steps:

(a) Raw materials were weighed according to the chemical formula Cs₃Cu₂I₅ of the composition of the intrinsically luminescent halide scintillation crystal to be prepared. During specific operation, high-purity materials CsI and CuI with a purity of 99.99% were weighed according to the molar ratio of CsCu₂I₃.

(b) In an inert gas environment, the materials were loaded into a quartz crucible with a capillary bottom; and the crucible was then vacuumized and sealed by welding. In this example, the inert gas environment was a glove box filled with argon or nitrogen.

(c) The sealed quartz crucible was vertically placed at the middle position in a crystal growing furnace, the crystal growing furnace was heated to about 650° C. (±30° C.) until the materials were completely melted and uniformly mixed, the crucible position and the temperature of furnace temperature were adjusted so that the temperature of the bottom of the crucible was decreased to about 390° C. (±30° C.), then the quartz crucible was descended at a descending rate of 0.4 mm/h in the furnace body, and crystals started to nucleate and grow from the capillary bottom of the crucible until the melt was completely solidified. Subsequently the temperature was lowered at a rate of 12° C./h to room temperature, and finally, a prepared halide scintillation crystal was taken out of the quartz crucible in a dry temperature and processed.

The aforementioned intrinsically luminescent halide scintillation crystal is used in the field of neutron detection, X-ray detection, or γ-ray detection.

The result of an X-ray excited emission spectrum test shows that the Cs₃Cu₂I₅ scintillation crystal has very strong X-ray excited luminescence. The result of γ-ray pulse height spectrum test shows that the Cs₃Cu₂I₅ scintillation crystal has a full-energy peak at 662 keV under the excitation of ¹³⁷Cs radioactive source, and has a better energy resolution and light output than CsCu₂I₃.

### Example 3:

The chemical formula of the composition of the intrinsically luminescent halide scintillation crystal proposed in this example is CsCu₂Br₃, i.e., (A₁₋ₓA′ₓ)(B_{1-y}B′_{y})₂(X_{1-z}X′_{z})₃ as the general formula, with A being Cs, B being Cu, X being Br, and x, y, and z being equal to 0.

The aforementioned intrinsically luminescent halide scintillation crystal was prepared by the Bridgman method, comprising the following steps:

(a) Raw materials were weighed according to the chemical formula (CsCu₂Br₃) of the composition of the intrinsically luminescent halide scintillation crystal to be prepared. During specific operation, high-purity materials CsBr and CuBr with a purity of 99.99% were weighed according to the molar ratio of CsCu₂Br₃.

(b) In an inert gas environment, the materials were loaded into a quartz crucible with a capillary bottom; and the crucible was then vacuumized and sealed by welding. In this example, the inert gas environment was a glove box filled with argon or nitrogen.

(c) The sealed quartz crucible was vertically placed at the middle position in a crystal growing furnace, the crystal growing furnace was heated to about 660° C. (±30° C.) until the materials were completely melted and uniformly mixed, the position of crucible and the temperature of furnace were adjusted so that the temperature of the bottom of the crucible was decreased to about 360° C. (±30° C.), the quartz crucible was then descended at a descending rate of 0.5 mm/h in the furnace body, crystals started to nucleate and grow from the capillary bottom of the crucible until the melt was completely solidified, the temperature was subsequently lowered at a rate of 15° C./h to room temperature, and finally, a prepared halide scintillation crystal was taken out of the quartz crucible in a dry temperature and processed.

The aforementioned intrinsically luminescent halide scintillation crystal is used in the field of neutron detection, X-ray detection, or γ-ray detection.

The result of an X-ray excited emission spectrum test shows that the CsCu₂Br₃ crystal has a weak X-ray excited luminescence. The result of γ-ray pulse height spectrum test shows that the CsCu₂Br₃ crystal has no obvious response under the excitation of ¹³⁷Cs radioactive source.

### Example 4:

The chemical formula of the composition of the intrinsically luminescent halide scintillation crystal proposed in Example 4 is (Cs_{0.99}Li_{0.01})3(Cu₀.₉₉₇Ag_{0.003})₂I₅, i.e., (A₁₋ₓA′ₓ)(B₁₋_{y}B′_{y})₂(X_{1-z}X′_{z})₃ as the general formula, with A being Cs, A′ being Li, B being Cu, B′ being Ag, X being I, x being equal to 0.01, y being equal to 0.003, and z being equal to 0.

The aforementioned intrinsically luminescent halide scintillation crystal was prepared by the Bridgman method, comprising the following steps:

(a) Raw materials were weighed according to the chemical formula ((Cs_{0.99}Li_{0.01})₃(Cu_{0.997}Ag_{0.003})₂I₅) of the composition of the intrinsically luminescent halide scintillation crystal to be prepared. During specific operation, high-purity materials CsI, LiI, CuI, and AgI with a purity of 99.99% were weighed according to the molar ratio of (Cs_{0.99}Li_{0.01})₃(Cu_{0.997} Ag_{0.003})₂I₅.

(b) In an inert gas environment, the materials were loaded into a quartz crucible with a capillary bottom, and the crucible was then vacuumized and sealed by welding. In this example, the inert gas environment was a glove box filled with argon or nitrogen.

(c) The sealed quartz crucible was vertically placed at the middle position in a crystal growing furnace, the crystal growing furnace was heated to about 650° C. (±30° C.) until the materials were completely melted and uniformly mixed, the position of crucible and the temperature of furnace were adjusted so that the temperature of the bottom of the crucible was decreased to about 400° C. (±30° C.), the quartz crucible was then descended at a descending rate of 0.8 mm/h in the furnace body, crystals started to nucleate and grow from the capillary bottom of the crucible until the melt was completely solidified, the temperature was subsequently lowered at a rate of 8° C./h to room temperature, and finally, a prepared halide scintillation crystal was taken out of the quartz crucible in a dry temperature and processed.

The aforementioned intrinsically luminescent halide scintillation crystal is used in the field of neutron detection, X-ray detection, or γ-ray detection.

### Example 5:

The chemical formula of the composition of the intrinsically luminescent halide scintillation crystal proposed in Example 5 is Cs₃(Cu_{0.99}Ag_{0.01})₂(I_{0.996}Br_{0.004})₅, i.e., A₁₋ₓA′ₓ)(B₁₋_{y}B′_{y})₂(X_{1-z}X′_{z})₃ as the general formula, with A being Cs, B being Cu, B′ being Ag, X being I, X′ being Br, x being equal to 0, y being equal to 0.01, and z being equal to 0.004.

The aforementioned intrinsically luminescent halide scintillation crystal was prepared by the Bridgman method, comprising the following steps:

(a) Raw materials were weighed according to the chemical formula Cs₃(Cu_{0.99}Ag_{0.01})₂(I_{0.996}Br_{0.004})₅ of the composition of the intrinsically luminescent halide scintillation crystal to be prepared. During specific operation, high-purity materials CsI, CuI, and AgBr with a purity of 99.99% were weighed according to the molar ratio of Cs₃(Cu_{0.99}Ag_{0.01})₂(I_{0.996}Br_{0.004})₅.

(b) In an inert gas environment, the materials were loaded into a quartz crucible with a capillary bottom; and the crucible was then vacuumized and sealed by welding. In this example, the inert gas environment was a glove box filled with argon or nitrogen.

(c) The sealed quartz crucible was vertically placed at the middle position in a crystal growing furnace, the crystal growing furnace was heated to about 650° C. (±30° C.) until the materials were completely melted and uniformly mixed, the position of crucible and the temperature of furnace were adjusted, so that the temperature of the bottom of the crucible was decreased to about 400° C. (±30° C.), the quartz crucible was then descended at a descending rate of 0.8 mm/h in the furnace body, crystals started to nucleate and grow from the capillary bottom of the crucible until the melt was completely solidified, the temperature was subsequently lowered at a rate of 18° C./h to room temperature, and finally, a prepared halide scintillation crystal was taken out of the quartz crucible in a dry temperature and processed.

The aforementioned intrinsically luminescent halide scintillation crystal is used in the field of neutron detection, X-ray detection, or γ-ray detection.

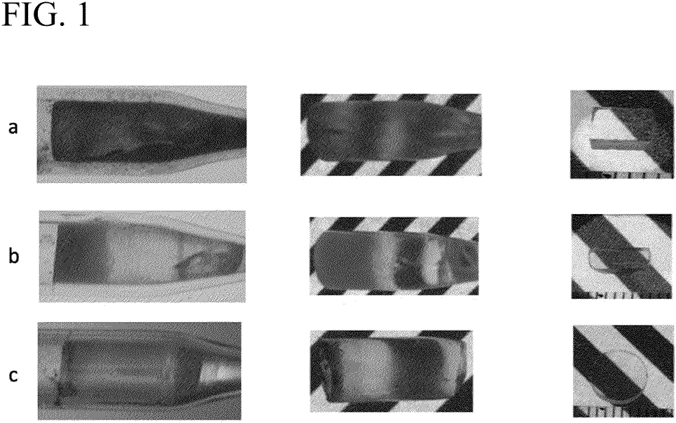

a to c of FIG. 1 show photos of ingots and samples of intrinsically luminescent halide scintillation crystals with different compositions. The composition of the crystal in a of FIG. 1 is CsCu₂I₃, the composition of the crystal in b of FIG. 1 is CsCu₂Br₃, and the composition of the crystal in c of FIG. 1 is Cs₃Cu₂I₅. The diameter of each of the three crystals in FIG. 1 is 7 mm, and the length of the equi-diameter part is 15 mm. It can be seen in FIG. 1 that high-quality monocrystals without cracks and inclusions can be grown with all the three components. Small samples were taken from the ingots for a performance test, the sample sizes respectively being 4×2×2 mm³, 5×2×1 mm³, and Φ7×2 mm³, as shown in FIG. 1.

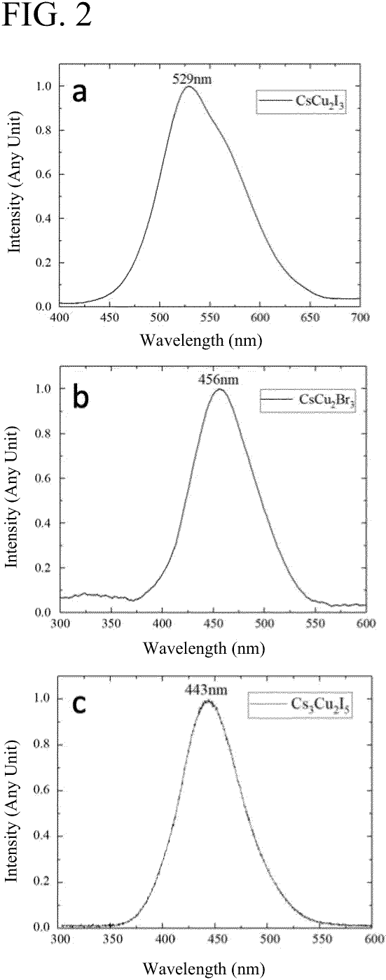

a to c of FIG. 2 show X-ray excited emission spectrums of the intrinsically luminescent halide scintillation crystals provided by the present invention with different compositions. a of FIG. 2 shows that the X-ray excited emission peak of CsCu₂I₃ is located at 529 nm. b of FIG. 2 shows that the X-ray excited emission peak of CsCu₂Br₃ is located at 456 nm. c of FIG. 2 shows that the X-ray excited emission peak of Cs₃Cu₂I₅ is located at 443 nm.

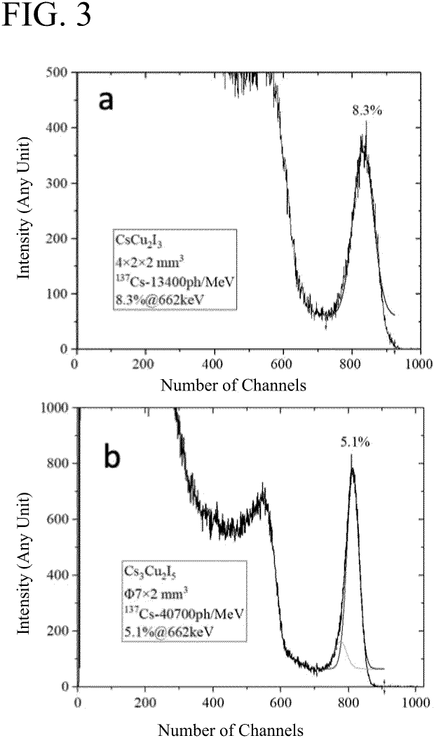

a and b of FIG. 3 show pulse height spectrums excited by ¹³⁷Cs radioactive source of the intrinsically luminescent halide scintillation crystals provided by the present invention with different compositions. In a of FIG. 3, the photomultiplier tube (PMT) used in the test was Hamamatsu R6231, and the selected formation time was 10 µs. Under these conditions, the light yield of CsCu₂I₃ was 13400 ph/MeV by calibration, and the energy resolution of the full-energy peak at 662 keV was about 8%. In b of FIG. 3, the photomultiplier tube (PMT) used in the test was Hamamatsu R6231, and the selected formation time was 10 µs. Under these conditions, the light yield of Cs₃Cu₂I₅ was 40700 ph/MeV by calibration, and the energy resolution of the full-energy peak at 662 keV was about 5%.

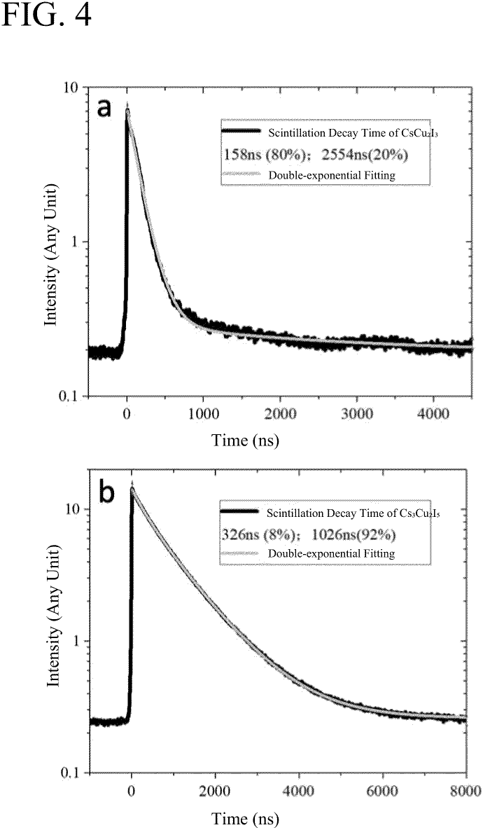

a and b FIG. 4 show scintillation decay times of the intrinsically luminescent halide scintillation crystals provided by the present invention with different compositions. a of FIG. 4 shows that the scintillation decay time of the CsCu₂I₃ crystal sample can be well-fitted by a double-exponential function, wherein, a fast component of its decay time is 158 ns, accounting for 80%, and a slow component is 2554 ns, accounting for 20%. b of FIG. 4 shows that the scintillation decay time of the CsCu₃I₅ crystal sample can be well-fitted by the double-exponential function, wherein, a fast component of its decay time is 326 ns, accounting for 8%, and a slow component is 1026 ns, accounting for 92%. It should be noted herein that the scintillation decay time of the CsCu₂Br₃ sample cannot be tested because it has no obvious response under the irradiation of 137Cs source.

### Example 6:

The chemical formula of the composition of the thallium-doped low-dimensional perovskite-structured microcrystalline thin film proposed in Example 6 is (Cs_{0.99}TI_{0.01})₃Cu₂I₅, i.e., (A_{1-a-b}A′ₐTl_{b})₃(B_{1-c}B′_{c})₂(X_{1-d}X’_{d})₅ as the general formula, with A being Cs, B being Cu, X being I, b being equal to 0.01, and a, c, and d being equal to 0.

The aforementioned thallium-doped low-dimensional perovskite-structured microcrystalline thin film was prepared by a vacuum evaporation method, and the corresponding preparation method comprises the following steps.

(Step 1) According to the molar ratio of the chemical formula ((Cs_{0.99}TI_{0.01})₃Cu₂I₅) of the composition of the thin film, high-purity materials (1.33 g of CsI, 0.66 g of CuI, and 0.017 g of TlI) with a purity of 99.99% were weighed. In an inert gas environment, all the materials were loaded into a quartz tube, and the crucible was heated above the melting points of the materials so that the materials were completely melted and uniformly mixed, and after cooling, a thallium-doped low-dimensional perovskite-structured compound material was synthesized. In Example 6, the inert gas environment was a glove box filled with argon or nitrogen.

(Step 2) A quartz glass substrate with a diameter of 50 mm as the coating substrate was ultrasonically cleaned with absolute ethanol for 10 min and dried with a hot air blower.

(Step 3) The clean and dry substrate was placed in a vacuum coating device, and 2 g of coating material was loaded into an evaporation boat with a corresponding volume. This was intended to avoid asynchronous evaporation caused by the large difference in the melting points between the halide materials and TlI. In Example 6, an evaporation boat loaded with 0.04 g of bead-like TlI was additionally added for synchronous evaporation with existing (Cs_{0.99}TI_{0.01})₃Cu₂I₅.

(Step 4) The vacuum coating device was vacuumized to 10⁻⁴ Pa, and meanwhile, the substrate was heated to 200° C.

(Step 5) When the vacuum degree and the temperature of the substrate became stable, the current was turned to heat, the input power was gradually adjusted until the vacuum degree decreased, the coating procedure was started, (Cs_{0.99}TI_{0.01})₃Cu₂I₅ was heated into a molten state, and bead-like TlI was heated until the TII beads turned red and black and were in a nearly sublimed state. After the evaporation was completed, a heating unit was turned off, and the temperature was naturally cooled down to room temperature. The obtained thallium-doped Cs₃Cu₂I₅ microcrystalline thin film was stored in a dry environment.

The result of an X-ray excited emission spectrum test shows that the thallium-doped Cs₃Cu₂I₅ microcrystalline thin film has strong X-ray excited luminescence, which indicates that the low-dimensional perovskite-structured microcrystalline thin film can be used in the fields of X-ray, γ-ray, and neutron detection and medical imaging, security inspection, industrial testing, etc.

### Example 7:

The composition of a thallium-doped low-dimensional perovskite-structured microcrystalline thin film proposed in this example is the same as that of the microcrystalline thin film proposed in Example 6, that is, the chemical formula is (Cs_{0.99}TI_{0.01})₃Cu₂I₅, i.e., (A₁₋ₐ₋_{b}A′ₐTl_{b})₃(B_{1-c}B′_{c})₂(X_{1-d}X’_{d})₅ as the general formula, with A being Cs, B being Cu, X being I, b being equal to 0.01, and a, c, and d being equal to 0.

The difference between the thallium-doped low-dimensional perovskite-structured microcrystalline thin film proposed in this example and Example 1 is that it was prepared by a sputtering method. The corresponding preparation method comprised the following steps:

(Step 1) According to the molar ratio of (Cs_{0.99}TI_{0.01})₃Cu₂I₅, high-purity materials (1.33 g of CsI, 0.66 g of CuI, and 0.017 g of TlI) with a purity of 99.99% were weighed. In an inert gas environment, all the materials were loaded into a quartz tube, the crucible was heated above the melting points of the materials so that the materials were completely melted and uniformly mixed, and, after cooling, a thallium-doped low-dimensional perovskite-structured compound material was synthesized. In Example 7, the inert gas environment was a glove box filled with argon.

(Step 2) A quartz glass substrate with a diameter of 50 mm as a coating substrate was ultrasonically cleaned with absolute ethanol for 10 min and dried with a hot air blower.

(Step 3) The clean and dry substrate was placed on a tray in a vacuum chamber of a sputtering system, a target made of the thallium-doped Cs₃Cu₂I₅ material was placed on a cathode target position, and a baffle was installed between the target and the tray.

(Step 4) The sputtering system in step 3 was vacuumized to 10⁻⁴ Pa, the substrate was heated to 200° C. at the same time, and high-purity argon was injected as a sputtering working gas.

(Step 5) When the vacuum degree and the temperature of substrate reached predestinate values, a radio-frequency power supply was switched on, input power was increased to a sputtering power, and pre-sputtering was carried out while maintaining working gas pressure. After pre-sputtering, sputtering was started while maintaining sputtering conditions. After sputtering was completed, the injection of the working gas was stopped, and the system returned to normal pressure. Sputtering and heating units were turned off, and the temperature was decreased to room temperature. The obtained thallium-doped Cs₃Cu₂I₅ microcrystalline thin film was stored in a dry environment.

The result of an X-ray excited emission spectrum test shows that the thallium-doped Cs₃Cu₂I₅ microcrystalline thin film has strong X-ray excited luminescence, which indicates that the low-dimensional perovskite-structured microcrystalline thin film can be used in the fields of X-ray and neutron detection, medical imaging, security inspection, industrial testing, etc.

### Example 8:

The chemical formula of the composition of a thallium-doped low-dimensional perovskite-structured microcrystalline thin film proposed in Example 8 is Cs_{0.99}TI_{0.01}Cu₂I₃, i.e., (A_{1-a-b}AₐTl_{b})(B₁-_{c}B_{c})₂(X_{1-d}X_{d})₃ as the general formula, with A being Cs, B being Cu, X being I, b being equal to 0.01, and a, c, and d being equal to 0.

The aforementioned thallium-doped low-dimensional perovskite-structured microcrystalline thin film was prepared by adopting a vacuum evaporation method. The corresponding preparation method comprised the following steps:

(Step 1) According to the molar ratio of the chemical formula (Cs_{0.99}TI_{0.01}Cu₂I₃) of the composition of the thin film, high-purity materials (0.80 g of CsI, 1.19 g of CuI, and 0.01 g of TlI) with a purity of 99.99% were weighed. In an inert gas environment, all the materials were loaded into a quartz tube, the temperature of crucible was increased above the melting points of the materials so that the materials were completely melted and uniformly mixed, and, after cooling, a thallium-doped low-dimensional perovskite-structured compound material was synthesized. In Example 8, the inert gas environment was a glove box filled with argon.

(Step 2) A quartz glass substrate with a diameter of 50 mm as the coating substrate was ultrasonically cleaned with absolute ethanol for 10 min, and dried.

(Step 3) The clean and dry substrate was placed in a vacuum coating device, and 2 g of coating material was loaded into an evaporation boat with a corresponding volume. This was intended to avoid asynchronous evaporation caused by the large difference in the melting points between the halide materials and TlI. In Example 8, an evaporation boat loaded with 0.04 g of bead-like TlI was additionally added for synchronous evaporation with existing Cs_{0.99}TI_{0.01}Cu₂I₃.

(Step 4) The vacuum coating device was vacuumized to 10⁻⁴ Pa, and meanwhile, the substrate was heated to 200° C.

(Step 5) When the vacuum degree and the temperature of substrate became stable, current heating was started, input power was gradually regulated until the vacuum degree decreased, the coating procedure was started, Cs_{0.99}TI_{0.01}Cu₂I₃ was heated into a molten state, and bead-like TlI was heated until the TII beads turned red and black and were in a nearly sublimed state. After evaporation was completed, a heating unit was turned off, and the temperature was naturally decreased to room temperature. The obtained thallium-doped CsCu₂I₃ microcrystalline thin film was stored in a dry environment.

The result of an X-ray excited emission spectrum test shows that the thallium-doped CsCu₂I₃ microcrystalline thin film has X-ray excited luminescence, which indicates that the low-dimensional perovskite-structured microcrystalline thin film can be used in the fields of X-ray and γ-ray detection, medical imaging, security inspection, industrial testing, etc.

### Example 9:

The chemical formula of the composition of a thallium-doped low-dimensional perovskite-structured microcrystalline thin film proposed in Example 9 is (Cs_{0.99}TI_{0.01})₂AgI₃, i.e., (A₁₋ₐ-_{b}AₐTl_{b})₂(B₁-_{c}B_{c})₂(X₁-_{d}X_{d})₃ as the general formula, with A being Cs, B being Ag, X being I, b being equal to 0.01, and a, c, and d being equal to 0.

The aforementioned thallium-doped low-dimensional perovskite-structured microcrystalline thin film was prepared by vacuum evaporation method. The corresponding preparation method comprised the following steps.

(Step 1) According to the molar ratio of the chemical formula ((Cs_{0.99}TI_{0.01})₂AgI₃) of the composition of the thin film, high-purity materials (1.45 g of CsI, 0.54 g of AgI, and 0.013 g of TlI) with a purity of 99.99% were weighed. In an inert gas environment, all the materials were loaded into a quartz tube, the temperature of crucible was increased above the melting points of the materials so that the materials were completely melted and uniformly mixed, and, after cooling, a thallium-doped low-dimensional perovskite-structured compound material was synthesized. In Example 9, the inert gas environment was a glove box filled with argon.

(Step 2) A quartz glass substrate with a diameter of 50 mm as the coating substrate was ultrasonically cleaned with absolute ethanol for 10 min, and dried.

(Step 3) The clean and dry substrate was placed in a vacuum coating device, and 2 g of coating material was loaded into an evaporation boat with a corresponding volume. This was intended to avoid asynchronous evaporation caused by large difference in the melting points between the halide materials and TlI. In Example 9, an evaporation boat loaded with 0.04 g of bead-like TlI was additionally added for synchronous evaporation with existing (Cs_{0.99}TI_{0.01})₂AgI₃.

(Step 4) The vacuum coating device was vacuumized to 10⁻⁴ Pa, and meanwhile, the substrate was heated to 200° C.

(Step 5) When the vacuum degree and the temperature of substrate became stable, current heating was started, input power was gradually regulated until the vacuum degree decreased, the coating procedure was started, (Cs_{0.99}TI_{0.01})₂AgI₃ was heated into a molten state, and bead-like TlI was heated until the TIIbeads turned red and black and were in a nearly sublimed state. After evaporation was completed, a heating unit was turned off, and the temperature was naturally decreased to room temperature. The obtained thallium-doped Cs₂AgI₃ microcrystalline thin film was stored in a dry environment.

The result of an X-ray excited emission spectrum test shows that the thallium-doped Cs₂AgI₃ microcrystalline thin film has X-ray excited luminescence, which indicates that the low-dimensional perovskite-structured microcrystalline thin film can be used in the fields of X-ray and γ-ray detection, medical imaging, security inspection, industrial testing, etc.

### Comparative Example 1:

Comparative Example 1 gives an example that does not conform to the three given general formulas, and the chemical formula of its composition is between (Cs_{0.99}TI_{0.01})₂CuI₃ and (Cs_{0.99}TI_{0.01})₃Cu₂I₅.

The aforementioned thallium-doped low-dimensional perovskite-structured microcrystalline thin film was prepared by vacuum evaporation method. The corresponding preparation method comprised the following steps.

(Step 1) Deviating from the molar ratio of the chemical formulas ((Cs_{0.99}TI_{0.01})₂CuI₃ and (Cs_{0.99}TI_{0.01})₃Cu₂I₅) of the composition of the thin film, high-purity materials (1.45 g of CsI, 0.55 g of CuI, and 0.01 g of TlI) with a purity of 99.99% were weighed. In an inert gas environment, all the materials were loaded into a quartz tube, the temperature of crucible was increased above the melting points of the materials so that the materials were completely melted and uniformly mixed, and, after cooling, a thallium-doped low-dimensional perovskite-structured compound material was synthesized. In Comparative Example 1, the inert gas environment was a glove box filled with argon.

(Step 2) A quartz glass substrate with a diameter of 50 mm as the coating substrate was ultrasonically cleaned with absolute ethanol for 10 min, and dried.

(Step 3) The clean and dry substrate was placed in a vacuum coating device, and 2 g of coating material was loaded into an evaporation boat with a corresponding volume. This was intended to avoid asynchronous evaporation caused by large difference in the melting points between the halide materials and TlI. In Comparative Example 1, an evaporation boat loaded with 0.04 g of bead-like TlI was additionally added for synchronous evaporation with the existing materials.

(Step 4) The vacuum coating device was vacuumized to 10⁻⁴ Pa, and meanwhile, the substrate was heated to 200° C.

(Step 5) When the vacuum degree and the temperature of substrate became stable, current heating was started, input power was gradually adjusted until the vacuum degree decreased, the coating procedure was started, the materials were heated into a molten state, and bead-like TlI was heated until the TII beads turned red and black and were in a nearly sublimed state. After evaporation was completed, a heating unit was turned off, and the temperature was naturally decreased to room temperature. The obtained thallium-doped CsCu₂I₃ microcrystalline thin film was stored in a dry environment.

The result of an X-ray excited emission spectrum test shows that the aforementioned thallium-doped low-dimensional perovskite-structured microcrystalline thin film has two different X-ray excited emission peaks at the same time, exhibiting the emission of nearly white light.

a and b of FIG. 6 are photos of a sample of the microcrystalline thin film obtained in Example 6 under different lights. This microcrystalline thin film is a thallium-doped Cs₃Cu₂I₅ microcrystalline thin film with a diameter of 50 mm. In a of FIG. 6, the sample is under natural light, showing a form of pale yellow translucent film. In b of FIG. 6, the sample is under ultraviolet light, exhibiting bright green light emission.

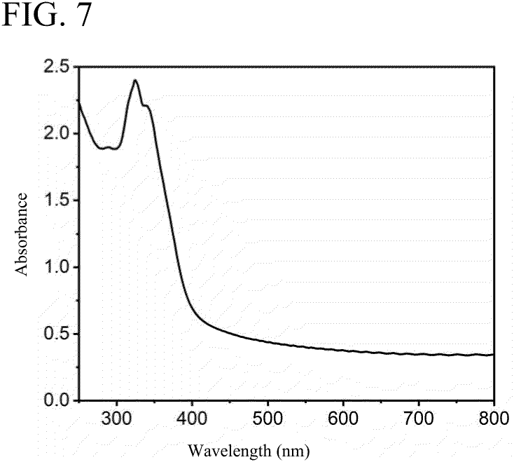

FIG. 7 shows an absorption spectrum of the microcrystalline thin film obtained in Example 6, and it can be seen that it has obvious absorption to ultraviolet light.

a of FIG. 8 shows a fluorescence spectrum of the microcrystalline thin film obtained in Example 6 under excitation at 300 nm, and it can be seen that the thallium-doped Cs₃Cu₂I₅ microcrystalline thin film has a 450 nm emission peak corresponding to self-trapped exciton luminescence under excitation at 300 nm. b of FIG. 8 shows a fluorescence spectrum of the microcrystalline thin film obtained in Example 6 under excitation at 335 nm, and it can be seen that the thallium-doped Cs₃Cu₂I₅ microcrystalline thin film has a 520 nm emission peak corresponding to Tl-related luminescence under excitation at 335 nm.

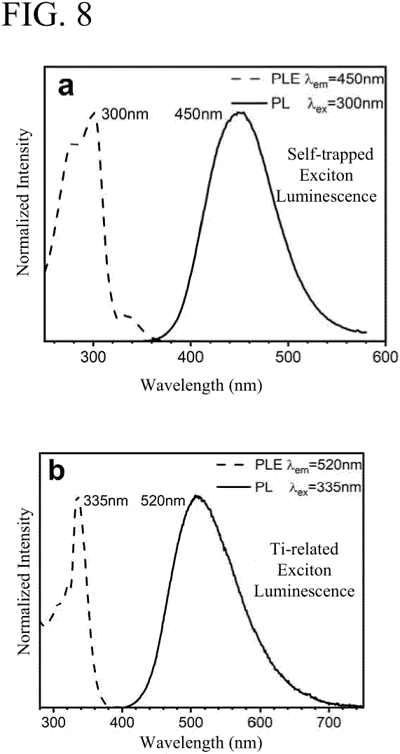

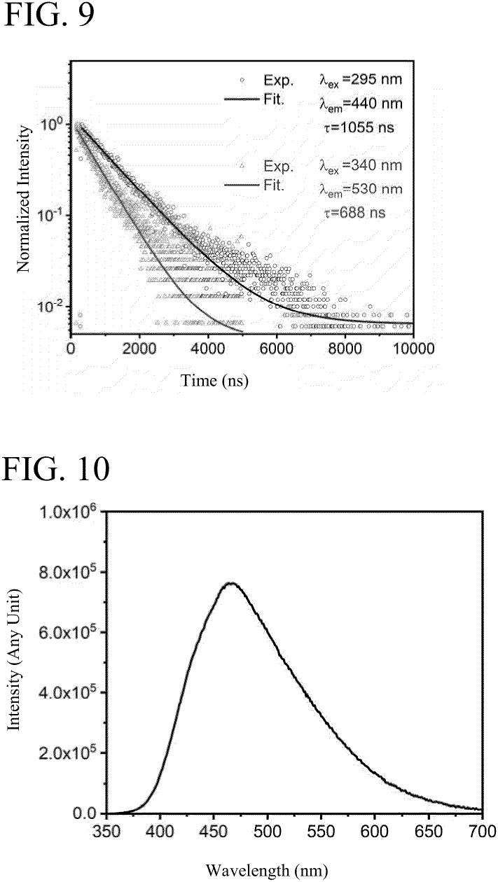

FIG. 9 shows fluorescence decay times of the two emission peaks ( shown in FIG. 8) of the microcrystalline thin film obtained in Example 6, and it can be seen that the fluorescence decay time corresponding to self-trapped exciton emission is 1055 ns and that the fluorescence decay time corresponding to Tl-related emission is 688 ns.

FIG. 10 shows an X-ray excited emission spectrum of the microcrystalline thin film (thallium-doped Cs₃Cu₂I₅ microcrystalline thin film) obtained in Example 6, and the X-ray excited emission curve of the thallium-doped Cs₃Cu₂I₅ microcrystalline thin film consists of self-trapped exciton luminescence and thallium-related luminescence.

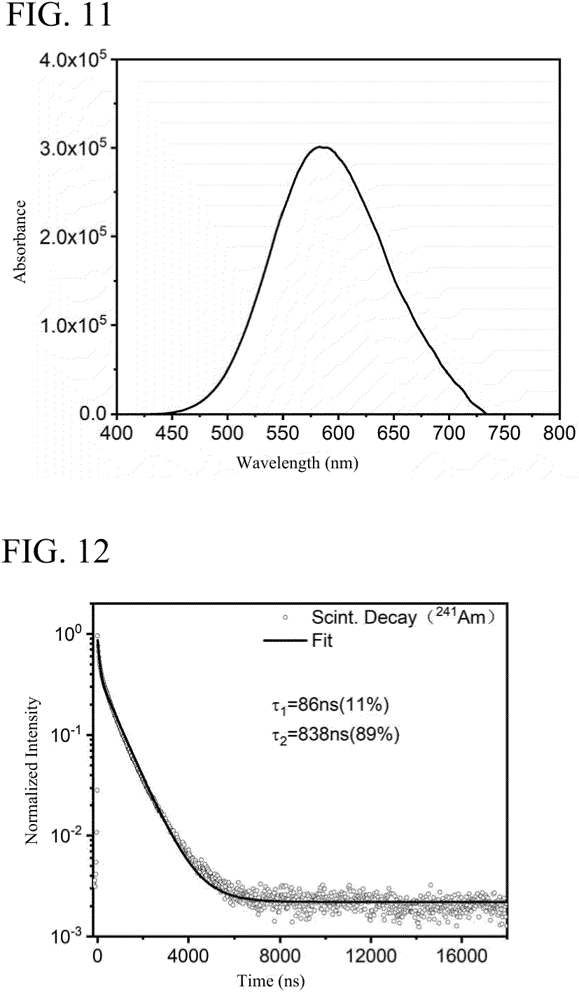

FIG. 11 shows an X-ray excited emission spectrum of the microcrystalline thin film (thallium-doped CsCu₂I₃ microcrystalline thin film) obtained in Example 8, and the X-ray excited emission curve of the thallium-doped CsCu₂I₃ microcrystalline thin film consists of self-trapped exciton luminescence and thallium-related luminescence. FIG. 12 shows the scintillation decay time of the microcrystalline thin film obtained in Example 6, showing that the scintillation decay time of the thallium-doped Cs₃Cu₂I₅ microcrystalline thin film sample can be fitted by the double-exponential function, wherein, a fast component of its decay time is 86 ns, accounting for 11%, and a slow component is 838 ns, accounting for 89%.

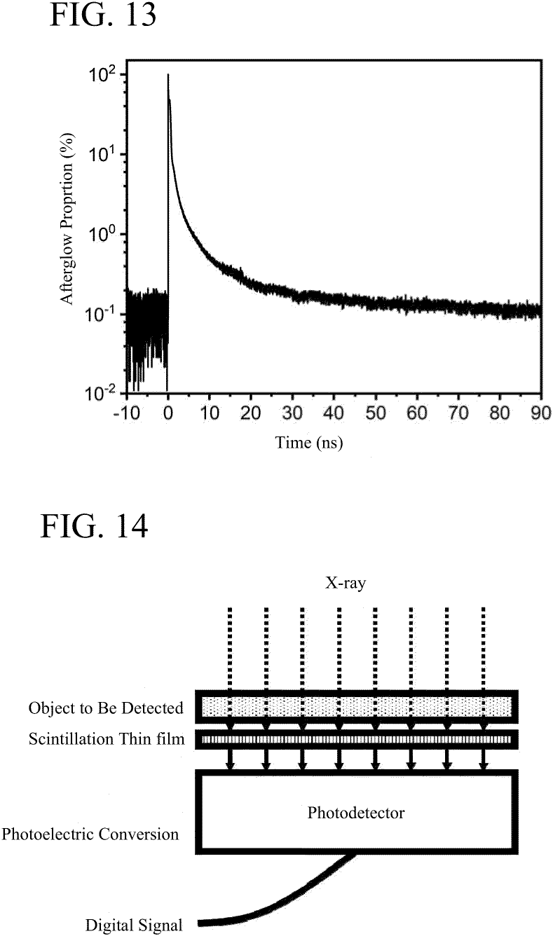

FIG. 13 shows an afterglow curve of the microcrystalline thin film obtained in Example 6, and it can be seen that the thallium-doped low-dimensional perovskite-structured thin film has a low afterglow effect.

FIG. 14 shows a schematic diagram of a detector composed of the microcrystalline thin film obtained in Example 6 and a photodetector. The operating mode of the detector is as follows: X-rays with a known intensity distribution are utilized to penetrate an object to be detected. Due to that substances with different densities and thicknesses have different X-ray absorption capacities, the intensity of the X-rays penetrating the object to be detected varies according to the densities and thicknesses of different parts of the object to be detected. After such an X-ray intensity distribution carrying the information of the object to be detected irradiates the microcrystalline thin film obtained in this example, it is converted into visible light with different intensities related to the different parts of the object to be detected. The visible light is converted into electrical signals by a photoelectric conversion device, and after information processing, a digital photo of the object to be detected is obtained.

Finally, it should also be noted that the above examples are only used to further illustrate the technical solution of the present invention in detail rather than to limit the protection scope of the present invention. All non-essential improvements and adjustments which are made by those skilled in the art according to the above contents of the present invention shall fall within the protection scope of the present invention.

1. A low-dimensional perovskite-structured metal halide, wherein
the general formulas of compositions of the low-dimensional perovskite-structured metal halide are AB₂X₃, A₂BX₃, and A₃B₂X₅; and
A is at least one of Li, Na, K, Rb, Cs, In, and Tl; B is at least one of Cu, Ag, and Au; and X is at least one of F, Cl, Br, and I.

2. The low-dimensional perovskite-structured metal halide of claim 1, wherein
the general formulas of the compositions of the low-dimensional perovskite-structured metal halide are (A₁₋ₓA′ₓ)(B_{1-y}B′_{y})₂(X_{1-z}X′_{z})₃, (A₁₋ₓA′ₓ)₂(B_{1-y}B′_{y})(X_{1-z}X′_{z})₃ and (A₁₋ₓA′ₓ)₃(B₁₋_{y}B′_{y})₂(X_{1-z}X′_{z})₅;
A and A′ are at least two of Li, Na, K, Rb, Cs, In and Tl;
B and B′ are at least two of Cu, Ag and Au;
X and X′ are at least two of F, Cl, Br and I; and
x is greater than 0 and less than 1, y is greater than 0 and less than 1, and z is greater than 0 and less than 1.

3. The low-dimensional perovskite-structured metal halide of claim 1, wherein
the general formulas of the compositions of the low-dimensional perovskite-structured metal halide are (A_{1-a-b}A′ₐTl_{b})(B_{1-c}B′_{c})₂(X_{1-d}X’_{d})₃, (A_{1-a-b}A′ₐTl_{b})₂(B_{1-c}B′_{c})(X_{1-d}X’_{d})₃, and (A₁₋ₐ₋_{b}A′ₐTl_{b})₃(B_{1-c}B′_{c})₂(X_{1-d}X’_{d})₅;
A and A′ are at least one of Li, Na, K, Rb, Cs and In;
B and B′ are at least one of Cu, Ag and Au;
X and X′ are F, Cl, Br and I; and
a is greater than or equal to 0 and less than 1, b is greater than 0 and less than or equal to 1, c is greater than or equal to 0 and less than or equal to 1, and d is greater than or equal to 0 and less than or equal to 1 .

4. The low-dimensional perovskite-structured metal halide of claim 1, wherein the low-dimensional perovskite-structured metal halide is a low-dimensional perovskite-structured metal halide scintillation crystal.

5. The low-dimensional perovskite-structured metal halide of claim 3, wherein
the low-dimensional perovskite-structured metal halide is a thallium-doped low-dimensional perovskite-structured metal halide microcrystalline scintillation thin film; and
the X-ray excited luminescence of the thallium-doped low-dimensional perovskite-structured microcrystalline scintillation thin film is 350 nm to 1200 nm .

6. A preparation method for the low-dimensional perovskite-structured metal halide scintillation crystal of claim 4, wherein the halide scintillation crystal is prepared by a Bridgman method, the Bridgman method comprising:
(1) weighing AX and BX as raw materials respectively according to the general formula of the composition of the low-dimensional perovskite-structured metal halide scintillation crystal, mixing the materials, loading the mixture into a crucible in a dry environment under inert gas, nitrogen or anhydrous environment, vacuumizing and sealing the crucible by welding;
(2) placing the sealed crucible into a Bridgman furnace, then heating up to a temperature exceeding the melting points of the raw materials by 50° C. to 100° C., so that the materials are completely melted, subsequently adjusting the temperature of the bottom of the crucible to decrease to the melting point of the low-dimensional perovskite-structured metal halide scintillation crystal, and starting crystal growth at a descending rate of 0.1 mm/h to 10.0 mm/h; and
(3) after the crystal growth is complete, cooling to room temperature to give a low-dimensional perovskite-structured metal halide scintillation crystal .

7. A thermal evaporation preparation method for the thallium-doped low-dimensional perovskite-structured metal halide microcrystalline scintillation thin film of claim 5, the thermal evaporation method comprising:
placing a substrate into a vacuum coating device;
loading coating material into an evaporation boat with a corresponding volume;
controlling the vacuum degree and temperature of the vacuum coating device; and
starting a coating procedure .

8. The preparation method of claim 7, wherein
when the coating material is loaded into the evaporation boat with the corresponding volume, an evaporation boat containing bead-like thallium halide is added to evaporate synchronously with the thallium-doped low-dimensional perovskite-structured compound; and
the mass ratio of the thallium-doped low-dimensional perovskite-structured compound to thallium halide is 99.99:0.01 to 90:10 .

9. (canceled)

10. An application of the low-dimensional perovskite-structured metal halide of claim 1 in the fields of neutron detection imaging, X-ray detection imaging, and γ-ray detection imaging.

11. The low-dimensional perovskite-structured metal halide of claim 3, wherein
the general formula of the composition of the low-dimensional perovskite-structured metal halide is (A_{1-a-b}A′ₐTl_{b})₃(B_{1-c}B′_{c})₂(X_{1-d}X’_{d})₅; and
A is Cs, B is Cu, X is I; a, c, and d are equal to 0; and b is greater than 0 and less than or equal to 0.1.

12. The low-dimensional perovskite-structured metal halide of claim 5, wherein
The coating material of the thallium-doped low-dimensional perovskite-structured microcrystalline scintillation thin film is a single-source coating material or a dual-source coating material;
the single-source coating material is a thallium-doped low-dimensional perovskite-structured compound synthesized according to (A_{1-a-b}A′ₐTl_{b})(B_{1-c}B′_{c})₂(X_{1-d}X’_{d})₃, (A_{1-a-b}A′ₐTl_{b})₂(B₁₋_{c}B′_{c})(X_{1-d}X’_{d})₃, or (A_{1-a-b}A′ₐT1_{b})₃(B_{1-c}B′_{c})₂(X_{1-d}X’_{d})₅;
and the dual-source coating material is a thallium-free low-dimensional perovskite-structured compound and thallium halide, or a synthesized thallium-doped low-dimensional perovskite-structured compound and thallium halide.

13. The preparation method for the low-dimensional perovskite-structured metal halide scintillation crystal of claim 6, wherein the crucible is a quartz crucible with a conical bottom or a capillary bottom, the purity of the materials is greater than or equal to 99.9%, and the inert gas is argon.

14. The preparation method of claim 7, wherein the vacuum degree of the vacuumized vacuum coating device is lower than 10⁻² Pa, and the substrate is heated to 20° C. to 300° C.

15. The preparation method of claim 7, wherein when the vacuum degree and the temperature of the substrate become stable, the coating procedure is started, and the coating material is heated to a molten state until the evaporation is completed.

16. A sputtering preparation method for the thallium-doped low-dimensional perovskite-structured metal halide microcrystalline scintillation thin film of claim 5, the sputtering method comprising:
placing a substrate onto a tray in a vacuum chamber of a sputtering system;
loading the coating material onto a cathode target position;
installing a baffle between a target and the tray;
controlling the vacuum degree and temperature of the sputtering system; and
starting a coating procedure.

17. The preparation method of claim 16, wherein the vacuum degree of the vacuumized vacuum coating device is lower than 10⁻² Pa, and the substrate is heated to 20° C. to 300° C.

18. The preparation method of claim 16, wherein when the vacuum degree and the temperature of the substrate become stable, the coating procedure is started, and the coating material is heated to a molten state until the evaporation is completed.

19. The preparation method of claim 16, wherein
the sputtering system is controlled so that the vacuum degree is lower than 10⁻² Pa, the substrate is heated to 20° C. to 300° C., and an inert gas is introduced as a sputtering working gas;
when the vacuum degree and the substrate temperature are stable, a radio-frequency power supply is switched on to carry out pre-sputtering; and
after the pre-sputtering, sputtering is started while maintaining sputtering conditions until sputtering is completed.
